(19) United States
(12) Patent Application Publication
(10) Pub. No.: US 2013/0222989 A1
(43) Pub. Date: Aug. 29, 2013

(54) ELECTRONIC DEVICE

(71) Applicant: Yi-Ting Chen, Taipei City (TW)

(72) Inventor: Yi-Ting Chen, Taipei City (TW)

(21) Appl. No.: 13/710,459

(22) Filed: Dec. 11, 2012

Related U.S. Application Data
(60) Provisional application No. 61/602,538, filed on Feb. 23, 2012.

(51) Int. Cl. G06F 1/16; H05K 5/02

(52) U.S. Cl. CPC G06F 1/16; H05K 5/0217
USPC 361/679.02; 361/679.01

(57) ABSTRACT

An electronic device including a first body, a second body, and a first rotational structure is provided. The first body includes a first inclined surface, and the second body includes a second inclined surface. The first rotational structure is connected to the first body and the second body. When the first inclined surface is rotated relative to the second inclined surface through the first rotational structure, a first angle is formed between the first body and the second body, and the first inclined surface is completely corresponding to the second inclined surface. Thereby, a high expandability and plentiful variations in the appearance of the electronic device can be achieved.

### CROSS-REFERENCE TO RELATED APPLICATION

This application claims the priority benefits of U.S. provisional application Ser. No. 61/602,538, filed on Feb. 23, 2012. The entirety of the above-mentioned patent application is hereby incorporated by reference herein and made a part of this specification.

### BACKGROUND OF THE DISCLOSURE

1. Field of the Disclosure

The disclosure generally relates to an electronic device, and more particularly, to an electronic device with two bodies.

2. Description of Related Art

In the current age of information explosion, electronic produces have been broadly used in our daily life. Along with the development of electronic technologies, electronic produces with high personality and functionality have been constantly developed. For example, tablet computers and notebook computers have become the most indispensable tools in our daily life because of their convenience and high portability. However, because tablet computers and notebook computers are small in size, their peripheral devices, such as CD-ROM and expansion ports, cannot meet all users' requirements. Thereby, related electronic devices for expansion purpose have been developed.

Electronic devices designed for tablet computers and notebook computers, such as external CD-ROM, hard discs, and speakers, are available in today's market. A user can purchase the desired electronic devices and carry them along with his tablet or notebook computer. However, it is not so convenient to carry different electronic devices, and a lot of space is taken when these electronic devices are placed on the desktop to be used.

### SUMMARY OF THE INVENTION

Accordingly, the disclosure is directed to an electronic device, in which multiple bodies are integrated to provide a high expandability to a host and to be carried conveniently, and these bodies can be rotated correspondingly and stood on the desktop to increase space efficiency.

The disclosure provides an electronic device including a first body, a second body, and a first rotational structure. The first body includes a first inclined surface, and the second body includes a second inclined surface. The first rotational structure is connected to the first body and the second body. When the first inclined surface is rotated relative to the second inclined surface through the first rotational structure, a first angle is formed between the first body and the second body, and the first inclined surface is completely corresponding to the second inclined surface.

According to an embodiment of the disclosure, the electronic device further includes a third body and a second rotational structure. The second body further includes a third inclined surface. The third body includes a fourth inclined surface. The second rotational structure is connected to the second body and the third body. When the third inclined surface is rotated relative to the fourth inclined surface through the second rotational structure, a second angle is formed between the second body and the third body, and the third inclined surface is completely corresponding to the fourth inclined surface.

As described above, in an electronic device provided by the disclosure, a first body and a second body are integrated to provide a high expandability to a host and to be carried conveniently. When the electronic device is placed on a desktop, a first inclined surface of the first body can be rotated relative to a second inclined surface of the second body to stand the second body relative to the first body, so that less desktop space is consumed and an attractive appearance is achieved.

Moreover, the first body and the second body can be electrically connected to the host through a wired or wireless manner to access data with the host. Furthermore, in an electronic device provided by the disclosure, the third body rotating relative to the second body can be further integrated to provide an even higher expandability and achieve more interesting three-dimensional shapes.

These and other exemplary embodiments, features, aspects, and advantages of the disclosure will be described and become more apparent from the detailed description of exemplary embodiments when read in conjunction with accompanying drawings.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1A is a diagram of an electronic device according to a first embodiment of the disclosure.

FIG. 1B is a diagram of the electronic device in FIG. 1A from another viewing angle.

FIG. 1C is a diagram illustrating how a first body is rotated relative to a second body in the electronic device illustrated in FIG. 1A.

FIG. 1D is a diagram illustrating how the first body is rotated relative to the second body in the electronic device illustrated in FIG. 1C from another viewing angle.

FIG. 1E is a diagram illustrating how the second body is stood relative to the first body in the electronic device illustrated in FIG. 1A.

FIG. 1F is a diagram illustrating how the second body is stood relative to the first body in the electronic device illustrated in FIG. 1E from another viewing angle.

FIG. 1G is a diagram of the electronic device in FIG. 1A connected to a host.

FIG. 2 is a diagram of an electronic device according to a second embodiment of the disclosure.

FIG. 3A is a diagram of an electronic device according to a third embodiment of the disclosure.

FIG. 3B is a diagram illustrating how a second body is rotated relative to a first body in the electronic device illustrated in FIG. 3A.

FIG. 3C is a diagram illustrating how a third body is rotated relative to the second body in the electronic device illustrated in FIG. 3A.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

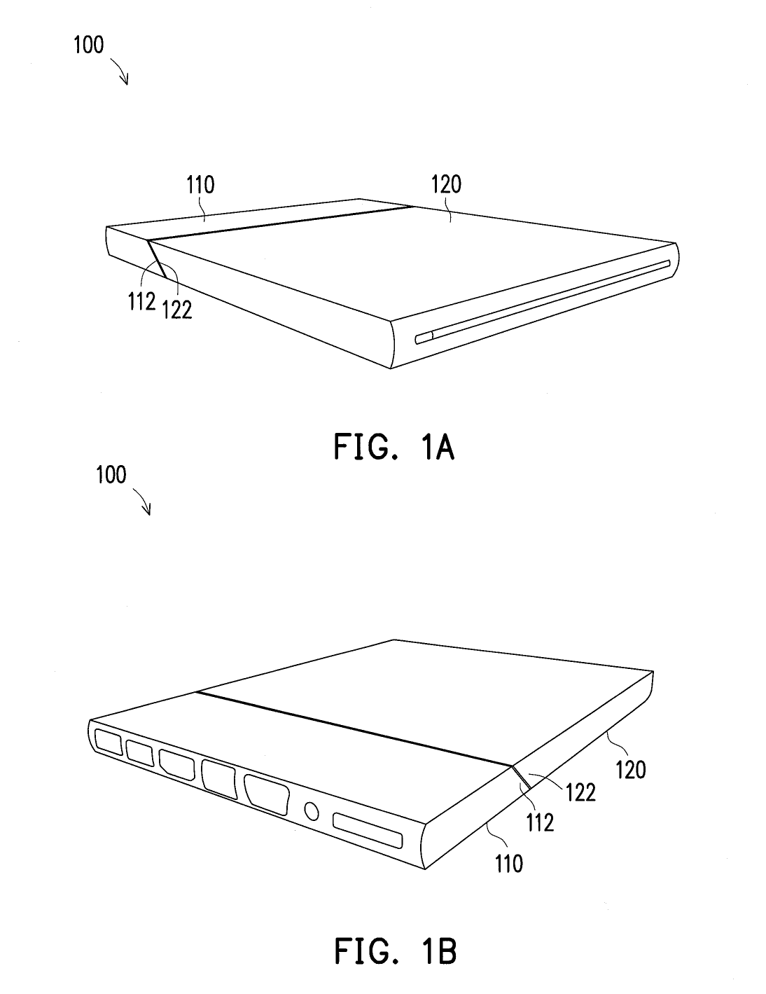

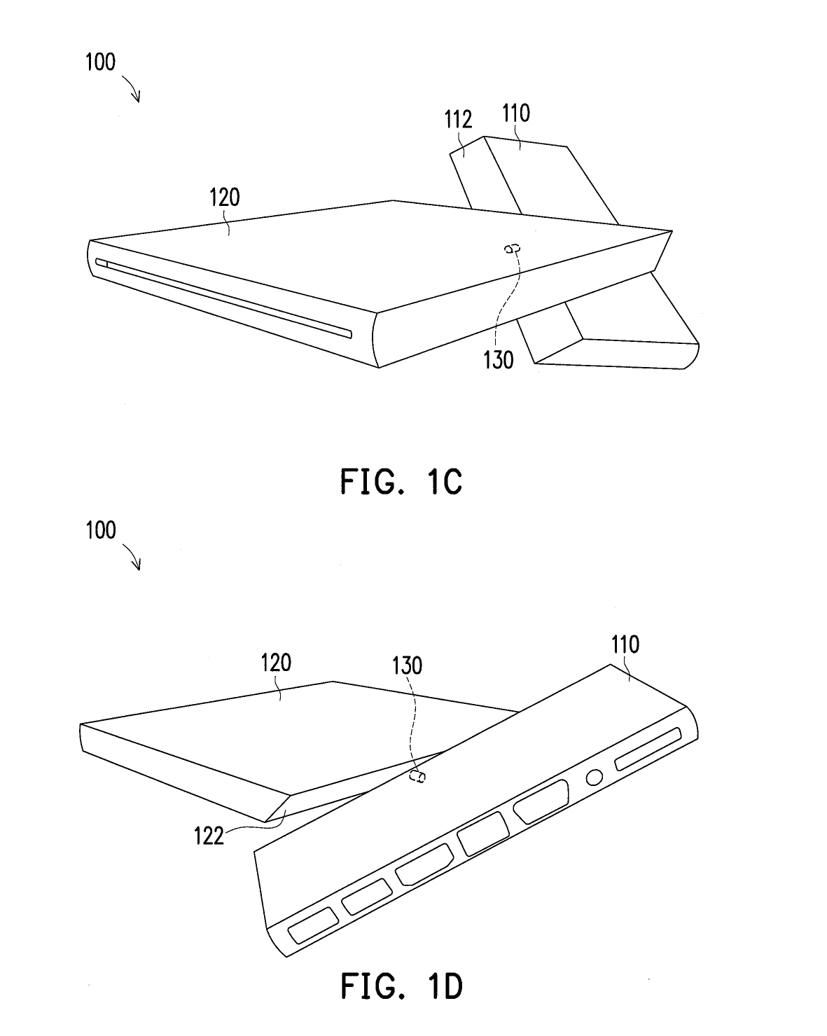

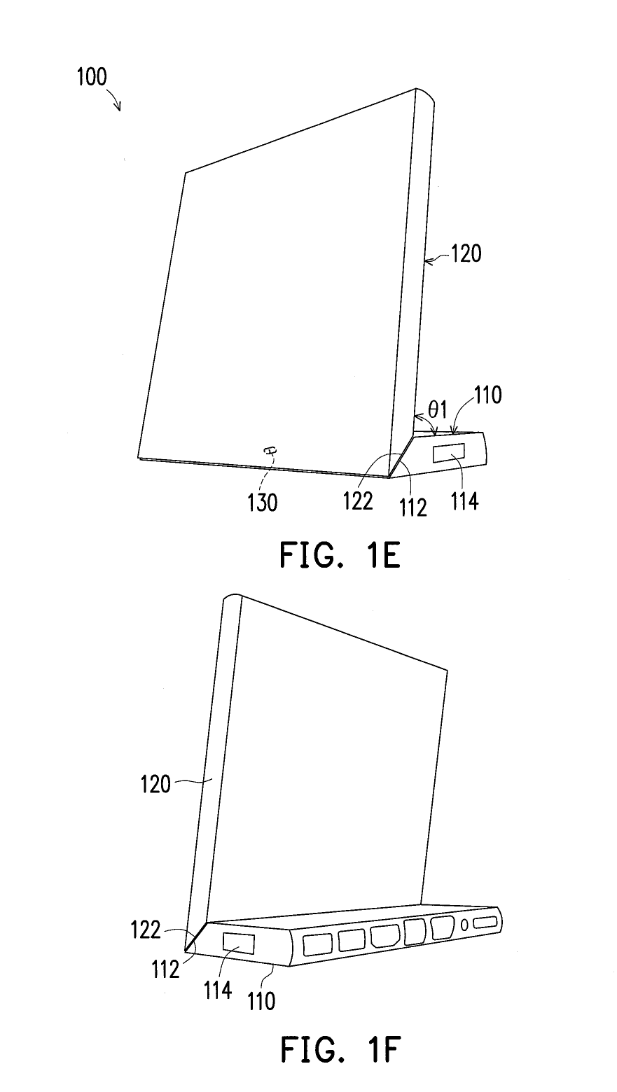

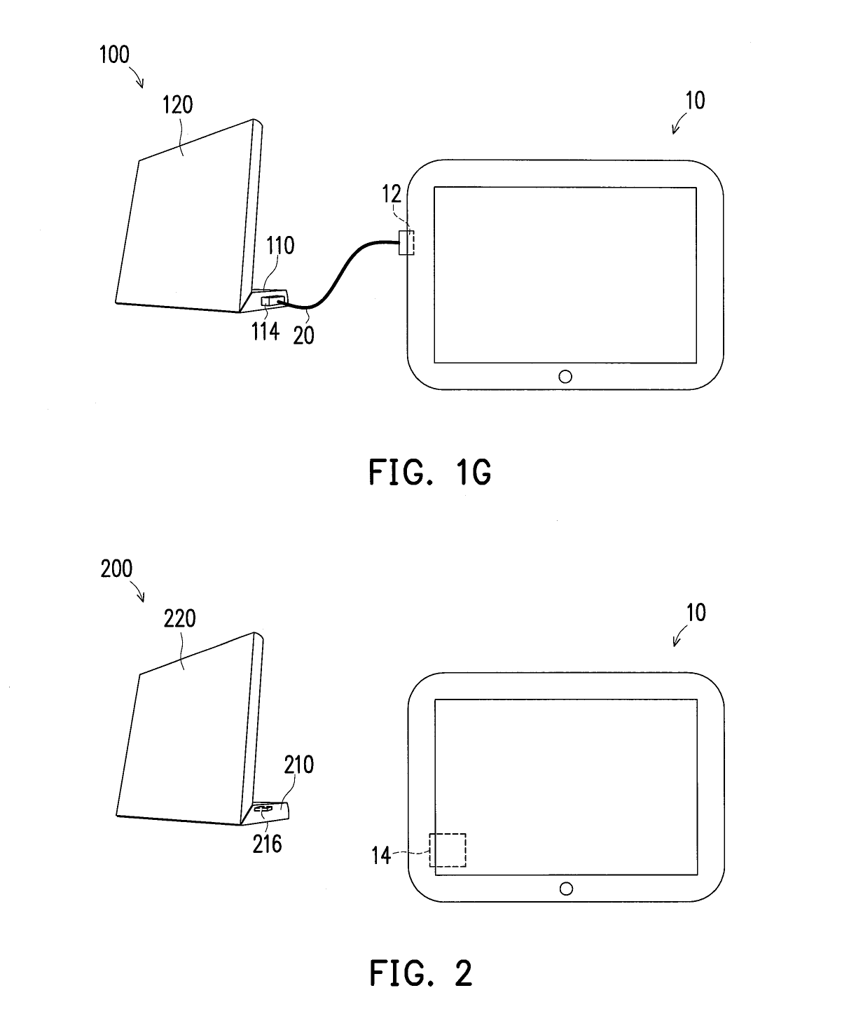

FIG. 1A is a diagram of an electronic device according to a first embodiment of the disclosure. FIG. 1B is a diagram of the electronic device in FIG. 1A from another viewing angle. Referring to FIG. 1A and FIG. 1B, the electronic device 100 in the present embodiment includes a first body 110, a second body 120, and a first rotational structure 130. The first body 110 and the second body 120 can be electrically connected to a host 10 to expand the functionality of the host 10. In the present embodiment, the host 10 is a tablet computer. However, the type of the host 10 is not limited herein, and in other embodiments, the host 10 may also be a notebook computer.

The first body 110 and the second body 120 may respectively include a CD-ROM, a hard disc, an input/output module, an image processing module, a speaker, a power supply, or a containing groove, etc. The input/output module may be a keyboard, a touch pad, or a plurality of expansion ports. The expansion ports may be high definition multimedia interfaces (HDMI) and video graphics array (VGA) interfaces. However, the types of the input/output module and the expansion ports are not limited herein.

In the present embodiment, the first body 110 includes an image processing module and a plurality of expansion ports, and the second body 120 includes a CD-ROM. However, the types of the first body 110 and the second body 120 are not limited thereto. In the present embodiment, the electronic device 100 integrates the first body 110 and the second body 120 to provide a high expandability to the host 10 and to be carried around by a user conveniently. Besides, because the first body 110 can be rotated relative to the second body 120, plentiful variations in the structure of the electronic device 100 can be achieved to meet different application requirements. This will be further explained below.

FIG. 1C is a diagram illustrating how the first body is rotated relative to the second body in the electronic device illustrated in FIG. 1A. FIG. 1D is a diagram illustrating how the first body is rotated relative to the second body in the electronic device illustrated in FIG. 1C from another viewing angle. Referring to FIG. 1C and FIG. 1D, in the present embodiment, the first body 110 includes a first inclined surface 112, and the second body 120 includes a second inclined surface 122. The first rotational structure 130 is connected to the first body 110 and the second body 120, and as shown in FIG. 1C, the first rotational structure 130 is located at the centers of the first inclined surface 112 and the second inclined surface 122. In the present embodiment, the shape of the first inclined surface 112 is the same as the shape of the second inclined surface 122, and the inclination angles thereof are corresponding to each other.

When the electronic device 100 is carried by a user, the electronic device 100 can be placed into a bag, as shown in FIG. 1A. When the electronic device 100 is to be used, to use less desktop space, the first body 110 can be rotated related to the second body 120 (as shown in FIG. 1C) to change the shape of the electronic device 100. The second inclined surface 122 of the second body 120 is rotated along the first inclined surface 112 of the first body 110 through the first rotational structure 130, so that the second body 120 is stood relative to the first body 110.

Herein a first angle θ1 is formed between the first body 110 and the second body 120, and the second body 120 is stood relative to the first body 110 for the first angle θ1. In the present embodiment, the first inclined surface 112 is completely corresponding to the second inclined surface 122. Namely, after the first body 110 is rotated relative to the second body 120, the first inclined surface 112 and the second inclined surface 122 are completely attached to each other. The first rotational structure 130 may be a pivotal structure such that the second inclined surface 122 of the second body 120 can be rotated relative to the first inclined surface 112 of the first body 110. However, this aspect is well known to those having ordinary knowledge in the art therefore will not be described herein.

FIG. 1E is a diagram illustrating how the second body is stood relative to the first body in the electronic device illustrated in FIG. 1A. FIG. 1F is a diagram illustrating how the second body is stood relative to the first body in the electronic device illustrated in FIG. 1E from another viewing angle. Referring to FIG. 1E and FIG. 1F, in the present embodiment, when the first inclined surface 112 of the first body 110 is rotated for 180° relative to the second inclined surface 122 of the second body 120, the second body 120 is stood up relative to the first body 110 (as shown in FIG. 1E), and the first body 110 contacts the second inclined surface 122 of the second body 120 through the first inclined surface 112 to prop up the second body 120.

Because the first body 110 has a small size therefore only takes up a small desktop space when it is in contact with the desktop. Thus, the user can place the electronic device 100 conveniently. Besides, the transfigured electronic device 100 offers a special visual effect. However, the rotation angle of the first inclined surface 112 of the first body 110 relative to the second inclined surface 122 of the second body 120 is not limited in the disclosure.

Additionally, corresponding pogo pin connectors can be disposed on the first body 110 and the second body 120 of the electronic device 100 at where the first rotational structure 130 is disposed, so as to electrically connect the first body 110 and the second body 120. This design with the pogo pin connectors ensures that the first body 110 and the second body 120 are electrically connected with each other regardless of the rotation angle, so that no more electric wire for electrically connecting the first body 110 and the second body 120 will be broken when the first body 110 is rotated relative to the second body 120. However, how the first body 110 and the second body 120 are electrically connected with each other is not limited in the disclosure.

FIG. 1G is a diagram of the electronic device in FIG. 1A connected to a host. Referring to FIG. 1G, in the present embodiment, the electronic device 100 is electrically connected with the host 10 through a wired manner. The host 10 includes a first transmission port 12, and the first body 110 includes a second transmission port 114 corresponding to the first transmission port 12. By connecting the first transmission port 12 and the second transmission port 114 with a transmission cable 20, data or power can be transmitted between the host 10 and the electronic device 100. The transmission interfaces of the first transmission port 12 and the second transmission port 114 may be universal serial bus (USB) interfaces or external Serial Advanced Technology Attachment (eSATA) interfaces. However, the transmission interfaces of the first transmission port 12 and the second transmission port 114 are not limited thereto. In other embodiments, the second transmission port 114 may be disposed on the second body 120, or the first body 110 and the second body 120 may respectively include a second transmission port 114.

FIG. 2 is a diagram of an electronic device according to a second embodiment of the disclosure. Referring to FIG. 2, the major difference between the electronic device 200 in FIG. 2 and the electronic device 100 in FIG. 1A is that in the present embodiment, the electronic device 200 and the host 10 are electrically connected with each other through a wireless manner. In the present embodiment, the host 10 includes a first wireless transmission module 14, and the first body 210 includes a second wireless transmission module 216 corresponding to the first wireless transmission module 14.

In other embodiments, the second wireless transmission module 216 may also be disposed on the second body 220, or the first body 210 and the second body 220 may respectively include a second wireless transmission module 216. If the first body 210 and the second body 220 respectively include a second wireless transmission module 216, any physical electrical connection (for example, aforementioned pogo pin connectors) between the first body 210 and the second body 220 can be omitted.

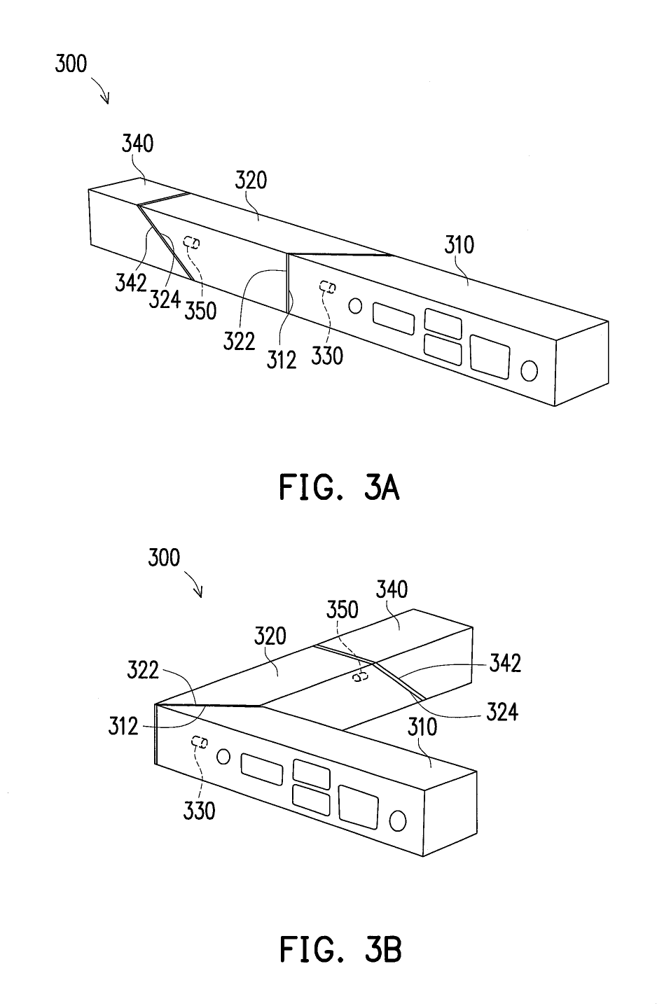

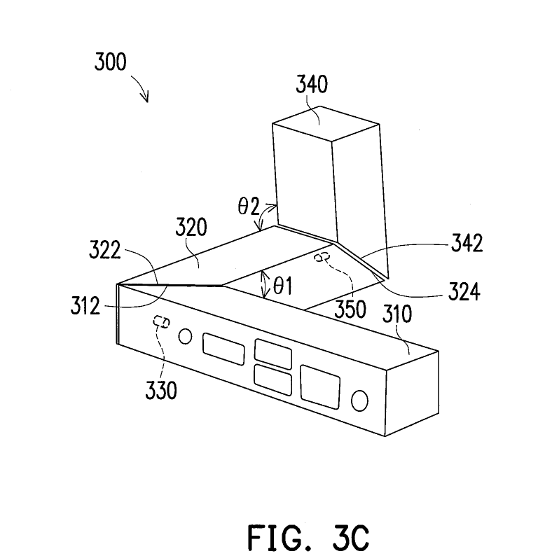

FIG. 3A is a diagram of an electronic device according to a third embodiment of the disclosure. Referring to FIG. 3A, the major difference between the electronic device 300 in FIG. 3A and the electronic device 100 in FIG. 1A is that the electronic device 300 in FIG. 3A further includes a third body 340 and a second rotational structure 350.

The second body 320 further includes a third inclined surface 324, and the third body 340 includes a fourth inclined surface 342. In the present embodiment, the second inclined surface 322 and the third inclined surface 324 of the second body 320 include different inclination angles and orientations. However, in other embodiments, the second inclined surface 322 may also be parallel to the third inclined surface 324.

The third body 340 may include a CD-ROM, a hard disc, an input/output module, an image processing module, a speaker, a power supply, or a containing groove. However, the type of the third body 340 is not limited thereto.

The second rotational structure 350 is connected between the second body 320 and the third body 340. In the present embodiment, a second rotational structure 350 is disposed at the centers of the third inclined surface 324 and the fourth inclined surface 342, and the shape of the third inclined surface 324 is the same as the shape of the fourth inclined surface 342. Thereby, the external profile of the third inclined surface 324 of the second body 320 matches the external profile of the fourth inclined surface 342 of the third body 340.

When the electronic device 300 is carried by a user, the electronic device 300 can be placed into a bag, as shown in FIG. 3A. How the electronic device 300 is used can be referred to FIG. 3B and FIG. 3C. FIG. 3B is a diagram illustrating how the second body is rotated relative to the first body in the electronic device illustrated in FIG. 3A. FIG. 3C is a diagram illustrating how the third body is rotated relative to the second body in the electronic device illustrated in FIG. 3A.

Referring to FIG. 3B and FIG. 3C, when the electronic device 300 is used, to use less desktop space, the second inclined surface 322 of the second body 320 can be rotated for 180° relative to the first inclined surface 312 of the first body 310, as shown in FIG. 3B.

As shown in FIG. 3C, the fourth inclined surface 342 of the third body 340 is rotated for 180° along the third inclined surface 324 of the second body 320 through the second rotational structure 350, so that the third body 340 is stood up relative to the first body 310 and the second body 320. As shown in FIG. 3C, a first angle θ1 is formed between the first body 310 and the second body 320, and a second angle θ2 is formed between the second body 320 and the third body 340. The first inclined surface 312 is completely corresponding to the second inclined surface 322, and the third inclined surface 324 is completely corresponding to the fourth inclined surface 342.

In other words, after the second body 320 is rotated relative to the first body 310, the second inclined surface 322 and the first inclined surface 312 are completely attached to each other, and after the third body 340 is rotated relative to the second body 320, the third inclined surface 324 and the fourth inclined surface 342 are completely attached to each other.

However, the transfiguration of the electronic device 300 is not limited in the disclosure, and it may also be contacting the desktop with only the second body 320 while standing the first body 310 and the third body 340 relative to the second body 320.

In the electronic device provided by the present embodiment, multiple bodies are integrated to provide a high expandability to the host, and by rotating the bodies, the electronic device is transfigured to be carried or placed conveniently or to achieve a user preferred appearance.

As described above, in an electronic device provided by the disclosure, a first body and a second body are integrated to provide a high expandability to a host and to be carried conveniently. When the electronic device is placed on a desktop, a first inclined surface of the first body can be rotated relative to a second inclined surface of the second body to stand the second body relative to the first body, so that less desktop space is consumed and an attractive appearance is achieved.

Moreover, the first body and the second body can be electrically connected to the host through a wired or wireless manner to transmit data back and forth with the host. Furthermore, in an electronic device provided by the disclosure, a third body rotating relative to the second body can be further integrated to provide an even higher expandability and achieve more interesting three-dimensional shapes.

It will be apparent to those skilled in the art that various modifications and variations can be made to the structure of the disclosure without departing from the scope of the disclosure. In view of the foregoing, it is intended that the disclosure cover modifications and variations of this disclosure provided they fall within the scope of the following claims and their equivalents.

What is claimed is:

1. An electronic device, comprising:
a first body, having a first inclined surface;
a second body, having a second inclined surface; and
a first rotational structure, connected to the first body and the second body, wherein when the first inclined surface is rotated relative to the second inclined surface through the first rotational structure, a first angle is formed between the first body and the second body, and the first inclined surface is completely corresponding to the second inclined surface.

2. The electronic device according to claim 1, wherein the first rotational structure is located at centers of the first inclined surface and the second inclined surface.

3. The electronic device according to claim 1, wherein a shape of the first inclined surface is the same as a shape of the second inclined surface.

4. The electronic device according to claim 1 further comprising a third body and a second rotational structure, wherein the second body further includes a third inclined surface, the third body includes a fourth inclined surface, the second rotational structure is connected to the second body and the third body, and when the third inclined surface is rotated relative to the fourth inclined surface through the second rotational structure, a second angle is formed between the second body and the third body, and the third inclined surface is completely corresponding to the fourth inclined surface.

5. The electronic device according to claim 4, wherein the second rotational structure is located at centers of the third inclined surface and the fourth inclined surface, and a shape of the third inclined surface is the same as a shape of the fourth inclined surface.

6. The electronic device according to claim 1, wherein at least one of the first body and the second body comprises a CD-ROM, a hard disc, an input/output module, an image processing module, a speaker, a power supply, or a containing groove.

7. The electronic device according to claim 6, wherein the input/output module comprises a keyboard, a touch pad, or a plurality of expansion ports.

8. The electronic device according to claim 1, wherein the first body or the second body is suitable for being electrically connected to a host.

9. The electronic device according to claim 8, wherein the host comprises a first transmission port, and the first body or the second body comprises a second transmission port corresponding to the first transmission port.

10. The electronic device according to claim 8, wherein the host comprises a first wireless transmission module, and the first body or the second body comprises a second wireless transmission module corresponding to the first wireless transmission module.
